(19) United States
(12) Patent Application Publication
(10) Pub. No.: US 2005/0205999 A1
(43) Pub. Date: Sep. 22, 2005

(54) Method for pattern metalization of substrates

(75) Inventors: Charles Forbes, Vineland, NJ (US); Alexander Gelbman, West Orange, NJ (US); Christopher Turner, Belmont, MA (US); Helena Gleskova, Princeton, NJ (US); Sigurd Richard Wagner, Princeton, NJ (US)

Correspondence Address: LAHIVE & COCKFIELD, LLP., 28 STATE STREET, BOSTON, MA, 02109, US

(73) Assignee: Visible Tech-knowledgy, Inc., West Orange, NJ (US)

(21) Appl. No.: 10/931,154

(22) Filed: Aug. 30, 2004

Related U.S. Application Data
(60) Provisional application No. 60/498,983, filed on Aug. 30, 2003.
(60) Provisional application No. 60/550,091, filed on Mar. 4, 2004.

(51) Int. Cl. H01L 23/48; H01L 21/4763

(52) U.S. Cl. 257/753; 438/628; 438/644; 257/763

(57) ABSTRACT

The present invention provides a method for forming an adhesion layer in contact with a first surface of a substrate and a surface of a layer having electrically conductive properties using electrophotographic imaging compound as a mask. The adhesion layer improves the lamination properties of the electrically conductive layer to the substrate. The improved lamination properties to facilitate and increase the reliability and quality of a resulting product having an electronic circuit formed in accordance with the present invention. The method disclosed herein is well suited for use with rigid polymeric substrates and flexible polymeric substrates.

### RELATED APPLICATION

This application claims priority to Provisional Application Ser. No. 60/498,983, filed Aug. 30, 2003, the contents of which are hereby incorporated by reference, and claims priority to Provisional Application Ser. No. 60/550,091, filed Mar. 1, 2004, the contents of which are hereby incorporated by reference.

### BACKGROUND OF THE INVENTION

The present invention is directed to the formation of structural features on a substrate, and is more particularly directed to adhesion of a conductive layer to the substrate.

Conventional photolithographic patterning techniques used in patterning wafers tends to be time consuming and costly. A significant portion of the cost and time associated with conventional photolithography is the development and fabrication of a mask. Another significant portion of the costs relate to investment costs, for example, capital equipment (e.g. a mask aligner) and higher material costs especially for photomasks and photoresists. Other significant costs contributing to the total costs of using photolithography as a patterning technique are associated with material handling, for example, material collection and disposal for waste solvents and photoresist.

Recent developments in integrated circuit fabrication techniques have reduced or overcome the burdens of long lead times and fabrication costs associated with the use of conventional masks. Such developments include electrophotographic imaging techniques for pattern formation, contact hole opening, and device isolation on a substrate. Electrophotographic imaging techniques use an image forming apparatus to apply electrophotographic imaging compounds, such as dry toner, to a substrate. The application of the electrophotographic imaging compounds to the substrate forms a mask suitable for use in forming structural patterns or features of an integrated circuit. As with most electrophotographic imaging techniques the desired pattern is first created on an electronic device, such as a computer and when completed, is transferred to the image forming apparatus for imaging on a selected medium or substrate. Masks of electrophotographic imaging compounds toner have been applied to glass substrates, polymeric substrates, both flexible and in rigid polymeric with modest success.

One burden of forming a mask with an electrophotographic imaging compound on a polymeric substrate is the adhesion of an initial conductive layer in a stack-up to a surface of the polymeric substrate. More specifically, the initial conductive layer in contact with the polymeric substrate tends to delaminate therefrom. This fact is particularly burdensome when the polymeric substrate is a flexible polymeric substrate.

The delamination of the initial conductive layer in contact with the surface of the polymeric substrate causes entire portions of stack up to lift from the substrate introducing quality and reliability issues in electronic goods. There accordingly exists a need in the art for improving the adhesion of an initial conductive layer in a stack-up of an integrated circuit or an electronic circuit to a polymeric substrate.

### SUMMARY OF THE INVENTION

The present invention addresses the above described limitations of forming an integrated circuit or an electronic circuit on a polymeric substrate. A method and electronic circuit is described herein that provides an approach to form an adhesion layer in contact with a surface of the polymeric substrate and a surface of a first conductive layer to improve the adhesion of the first conductive layer of the electronic circuit or integrated circuit to the polymeric substrate.

In one illustrative embodiment of the present invention, a method for forming a conductive element on a first surface of a substrate is disclosed. The method includes steps of forming an adhesion layer on a portion of the first surface of the substrate and forming the conductive element on the adhesion layer. The method can further include a step of forming a mask of an electrophotographic imaging compound on the first surface of the substrate and heating the substrate with the mask formed thereon to an elevated temperature for a selected period of time.

The method can further include a step of removing at least a portion of the mask from the first surface of the substrate. In one aspect of the present invention, a stiffener is provided and the substrate is affixed thereto to stiffen the substrate during the step of forming the mask on the selected surface of the substrate and if desired to stiffen the substrate during the formation of the adhesion layer, and if desired during formation of the conductive element on the adhesion layer.

The method can also include steps to form a double sided electronic circuit. By performance of the steps of forming, an adhesion layer on a portion of a second surface of the substrate and forming a conductive element on the adhesion layer formed on the second surface of the substrate the present invention is well suited for use in producing double sided electronic circuits.

The method disclosed herein can further include a step of forming a dielectric layer on a portion of the first surface of the substrate. The dielectric layer can include silicon nitride (SiNx), silicon nitride (Si₃N₄), silicon dioxide (SiO₂) or another suitable material for use as a dielectric layer. Suitable methods for forming the adhesion layer include, but are not limited to electron deposition, thermal deposition, sputtering, plasma deposition, plating, either with an electrode or in an electrodeless manner, spraying, or other suitable technique. A substrate suitable for use with the method of the present invention can be rigid or flexible and can include materials such as one or more polymers, glass, silicon, lignocellulosic, fabric or other conventional substrate material such as gallium arsenide (GaAs) and variations thereof.

In another illustrative embodiment of the present invention, an electronic circuit is disclosed. The electronic circuit includes a substrate, an adhesion layer in contact with a portion of a first surface of the substrate, and a conductive path in contact with a portion of the adhesion layer. The conductive path couples a portion of a first electronic device of the electronic circuit to a second portion of a second electronic device of the electronic circuit.

The electronic circuit can further include a dielectric layer in contact with a portion of the substrate and a portion of the adhesion layer. Further, the electronic circuit can be a double sided electronic circuit with an adhesion layer in contact with a portion of a second surface of a polymeric substrate and a conductive path in contact with a portion of the adhesion layer in contact with the portion of the second surface of the substrate. The conductive path couples a portion of a third electronic device of the electronic circuit to a fourth electronic device of the electronic circuit.

### BRIEF DESCRIPTION OF THE DRAWINGS

The foregoing and other objects, features and advantages of the invention will be apparent from the following description and apparent from the accompanying drawings, in which like reference characters refer to the same parts throughout the different views. The drawings illustrate principals of the invention and, although not to scale, show relative dimensions.

FIG. 1 is a block diagram illustrating an exemplary environment suitable for creating a mask and imaging the mask on a substrate in accordance with the teachings of the present invention.

FIG. 2 is a block diagram illustrating a suitable environment for forming the adhesion layer and the conductive element on the substrate in accordance with the teachings of the present invention.

FIG. 3 is a top view of a substrate having formed thereon a mask in accordance with the teachings of the present invention.

FIG. 4 is a side view of the substrate in FIG. 3 illustrating the mask formed thereon in accordance with the teachings of the present invention.

FIG. 5 is a side view of the substrate in FIG. 3 illustrating an adhesion layer formed thereon in accordance with the teachings of the present invention.

FIG. 6 is a side view of the substrate in FIG. 3 illustrating a conductive element formed thereon in accordance with the teachings of the present invention.

FIG. 7 is a side view of the substrate in FIG. 3 illustrating the substrate after cleaning to remove the mask and any overlying material layer in accordance with the teachings of the present invention.

FIG. 8 is a block flow diagram illustrating steps taken to perform one illustrative embodiment of the present invention.

FIG. 9 is a block flow diagram illustrating steps taken to perform a second illustrative embodiment of the present invention.

FIG. 10 illustrates a side view of a substrate having an inorganic substance coated on the top surface and bottom surface in accordance with the teachings of the present invention.

FIG. 11 illustrates a first double sided electronic circuit formed in accordance with the teachings of the present invention.

FIG. 12 illustrates a second double sided electronic circuit formed in accordance with the teachings of the present invention.

FIG. 13 illustrate a side view of a portion of an electronic display having and electronic circuit formed in accordance with the teachings of the present invention.

FIG. 14 illustrates a substrate material suitable for use in practicing the illustrative embodiment of the present invention.

### DETAILED DESCRIPTION

The present invention is directed to an electronic circuit having an adhesion layer in contact with a surface of a substrate and a surface of a conductive element and to a method for forming the adhesion layer and the conductive element on the substrate. The formation of the adhesion layer is accomplished by imaging a mask of an electrophotographic imaging compound onto a substrate using an image forming apparatus, and forming the adhesion layer on the mask and the substrate, and, in turn, forming the conductive element on the adhesion layer. The mask provides the desired structural pattern for the resulting conductive element. The adhesion layer is formed from a material, for example, titanium (Ti), chromium (Cr), nickel (Ni), aluminum (Al), copper (Cu), silicon dioxide (SiO₂), silicon nitrate (SiNₓ), or other suitable material or compound having properties or a structure well suited for adhering to a surface of a selected substrate type. In this manner, the conductive element adheres to the adhesion layer, which, in turn adheres to the surface of the substrate to provide an approach that improves the lamination of a conductive element to a substrate surface in an electronic circuit.

Before proceeding with the remainder of the detailed description, it is first helpful to define a few terms used throughout the disclosure.

As used herein, the term “image forming apparatus” refers to an apparatus or device for depositing on a medium an electrophotographic imaging compound. Examples of an image forming apparatus include, but are not limited to, a laser printer, a xerographic imaging device, a facsimile machine, and other like apparatuses or devices that form an image on a medium using electrophotographic imaging compounds.

As used herein, the term “conductive element” refers to a conductive path, a portion of a conductive path, an electronic device, or a portion of an electronic device, formed from a conductive or semiconductive material or compound. The conductive path or portion of a conductive path provides a transmission medium capable of transmitting an analog signal, a digital signal, or a power signal alone or as part of a power grid, or as a conductive path to ground or a portion of a ground plane.

As used herein, the term “electronic device” refers a transistor, a portion of a transistor such as a gate, drain or source, an inductor, a capacitor, or a resistor.

As used herein, the term “organic solvent” includes any non-aqueous solution chosen from the ketone group, such as acetone, methylisobutyl ketone; the aromatic solvent group, such as toluene, xylene; the ester group, such as ethyl acetate, methoxyproply acetate; the ether group, such as diethyl ether; and other solvents such as dimethyl formamide, N-methylpyrolidone, or gamma-butyrolactone.

As used herein, the term “substrate” refers to a rigid substrate with little or no ability to flex in any number of dimensions or to a substrate having properties that allow the substrate to flex (i.e. conformable) in a plurality of dimensions. Examples of substrates include, but are not limited to, silicon substrates, glass substrates, glass foil substrates, polymeric substrates, gallium arsenide substrates, indium phosphate, and other like substrates. Examples of electrophotographic patterning on glass foil are discussed in detail in U.S. Pat. No. 6,080,606, entitled “Electrophotographic Patterning of Thin Film Circuits”, the contents of which are incorporated herein by reference.

As used herein, the term “polymeric substrate” includes such polymers as polyimides, polyvinyls, polybenzimideazoles, polyesters, polyacrylates, polyamides, polybenzimidazole, celluloid, or other polymers suitable for use in the fabrication of an electronic circuit.

As used herein, the term “material source” includes such material sources as electron beam systems, thermal evaporation systems, chemical vapor deposition tools, enhanced chemical vapor deposition tools, sputtering systems, spray systems, platting systems including electrode platting systems and electrodeless plating systems and other like systems capable of depositing one or more selected materials of compounds on a substrate.

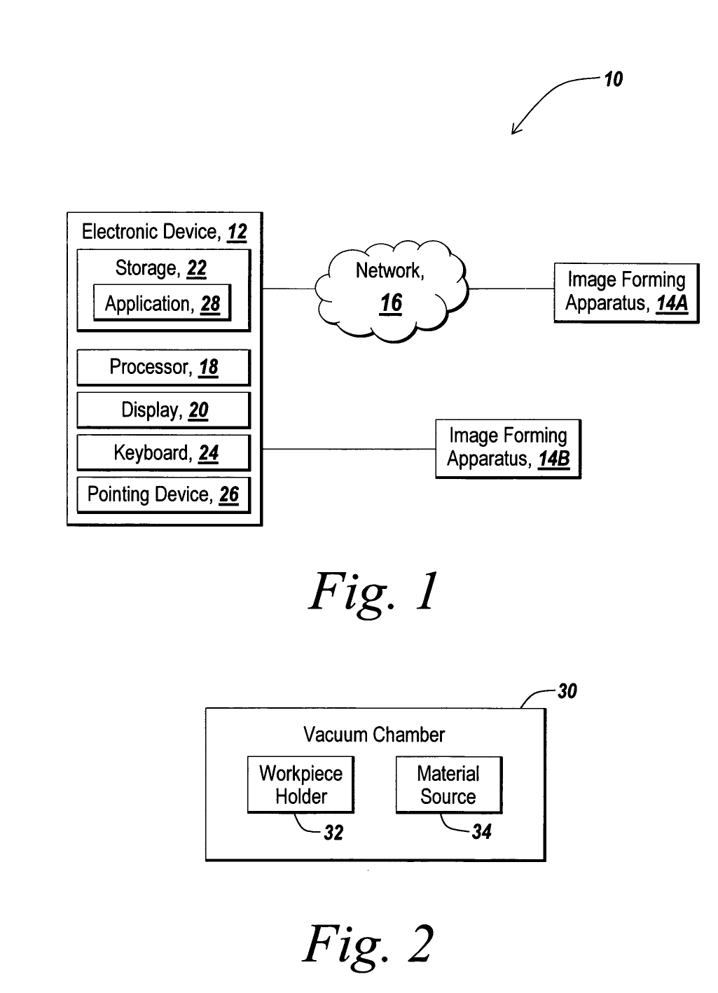

FIG. 1 illustrates an environment suitable for creating a mask and imaging the mask on a substrate in accordance with the teachings of an illustrative embodiment of the present invention. A computer system 10 includes an electronic device 12, a network 16, such as the Internet, an intranet, or other suitable network, either wired or wireless, or a hybrid of wired and wireless, and an image forming apparatus 14A. Alternatively, or in addition to, the computer system 10 can include image forming apparatus 14B coupled directly to electronic device 12 through a cable or other medium capable of handling serial data, parallel data or both.

The electronic device 12 includes a processor 18 for executing various instructions and programs, and controlling various hardware and software components. The electronic device 12 also includes a display device 20 for use in rendering textual and graphical images, a storage device 22 for storing various items such as data, information, and programs. A keyboard 24 and a pointing device 26 are also included with the electronic device 12. The pointing device 26 includes such devices as a mouse, track ball, or light pen. Those skilled in the art will recognize that the pointing device 26 can be incorporated with the display device 22 to provide the electronic device 12 with a touch screen that allows the user to interact with the electronic device 12 with a stylist or with other means such as a user's finger.

The storage device 22 includes an application 28 for use in creating and developing masks having a desired graphical or structural pattern. One suitable application for use in creating or developing a mask in accordance with the illustrative embodiment of the present invention is Adobe® PostScript® available from Adobe Systems Incorporated, of San Jose, Calif. Nevertheless, those skilled in the art will recognize that other suitable applications are available for use in creating or developing a mask in accordance with the illustrative embodiment of the present invention for example, other such applications can include, but are not limited to, CorelDRAW® available from Corel Corporation of Ottawa, Canada; and Adobe® Photoshop® available from Adobe Systems Incorporated, of San Jose, Calif. Those skilled in the art will recognize that the electronic device 12 includes other software such as, various user interfaces and other programs, such as one or more OS programs, compilers, drivers, and various other program applications developed in a variety of programming environments for controlling system software and hardware components.

FIG. 2 illustrates an exemplary environment for forming the adhesion layer and the conductive element on the substrate in accordance with the teachings of the present invention. Vacuum chamber 30 includes workpiece holder 32 and a material source 34. The workpiece holder 32 has a structure for holding a substrate having formed thereon a mask during formation of an adhesion layer and a conductive element according to the structural pattern defined by the mask. The material source 34 deposits the material or materials selected for the adhesion layer and the conductive element as defined by the mask. One suitable material source for use in practicing the illustrative embodiment of the present invention includes a Denton electron beam evaporator available from Denton Vacuum of Moorestown, N.J. Those skilled in the art will appreciate that vacuum chamber 30 can include other equipment including a mechanical scanner or an electrostatic scanner, vacuum pumps, water cooling elements and one or more control systems for controlling operation of the vacuum chamber and the material source 34.

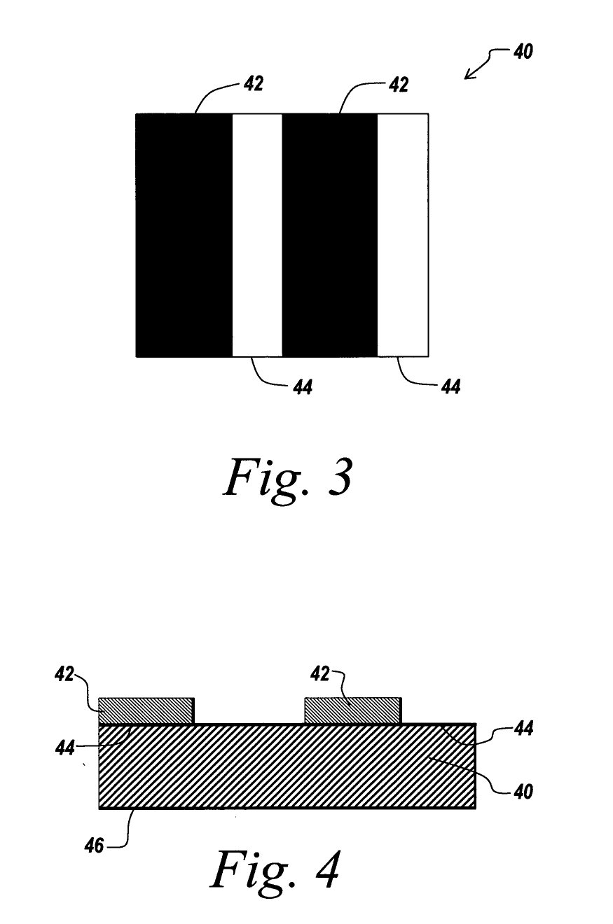

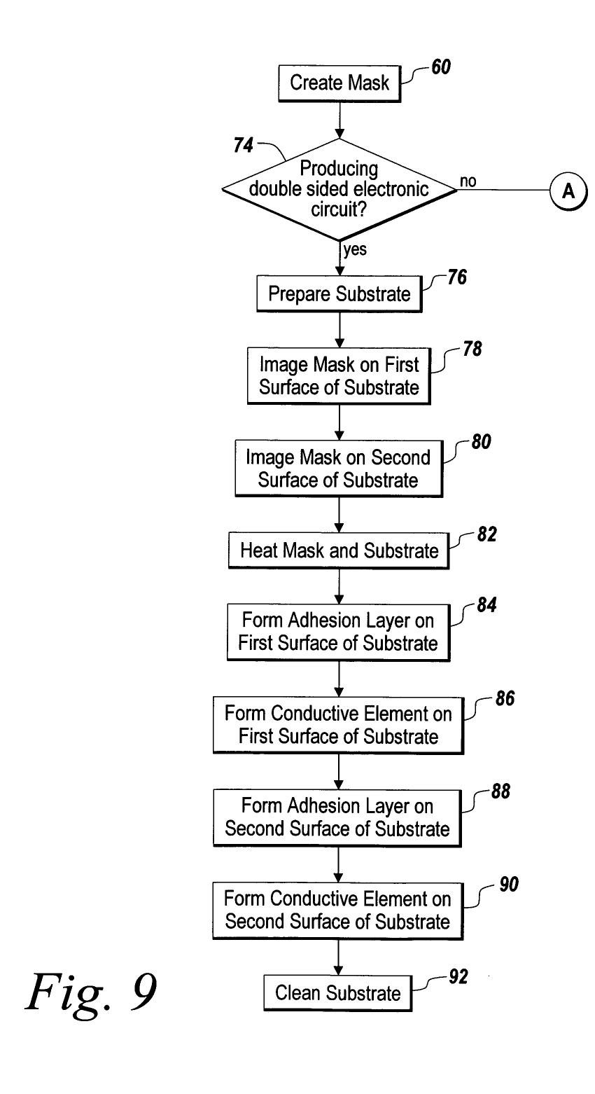

FIG. 3 illustrates a top view of a substrate 40 having formed on a first surface 44, a mask 42. Those skilled in the art will appreciate that the illustration of mask 42 is meant to facilitate explanation of the present invention and the mask 42 can take the form of any desired graphical shape capable of being formed by the application 28 and the image forming apparatus 14A or 14B. Moreover, those skilled in the art will appreciate that the line width or resolution of the mask formed with system 10 is a function of the particle size of the electrophotographic imaging compound used and the resolution (dpi) of the image forming apparatus. As illustrated in FIG. 3, the mask 42 represents a negative resist mask. As such, portions of the first surface 44 of the substrate 40 covered with the mask 42 will be free of additional layers formed thereon upon removal or cleaning of the mask 42 from the first surface 44. The steps taken to form the elements illustrated in FIGS. 3-7 are discussed in detail with regard to FIGS. 8 and 9.

FIG. 4 illustrates a side view of the substrate 40 having formed thereon the mask 42 as illustrated in FIG. 3.

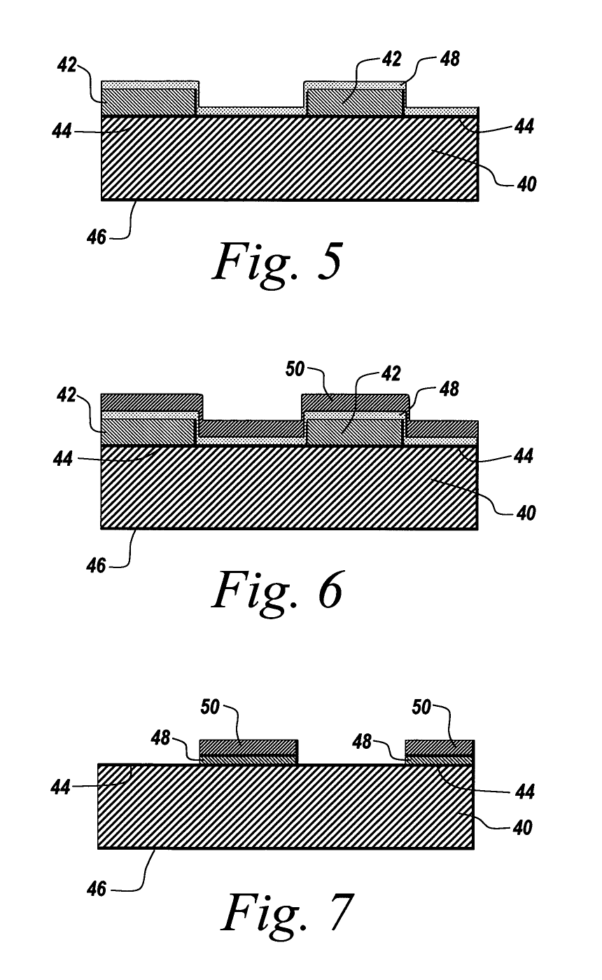

FIG. 5 illustrates a side view of the substrate 40 having formed on the first surface 44 an adhesion layer 48. As illustrated, the adhesion layer 48 contacts a portion of the first surface 44 of the substrate 40 free of the mask 42, and contacts the mask 42. The substrate 40 includes a second surface 46 suitable for use in forming a double sided electronic device, which will be discussed in more detail with regard to FIGS. 9, 11, and 12.

FIG. 6 illustrates a side view of the substrate 40 having formed on the first surface 44, the mask 42, the adhesion layer 48, and conductive element 50.

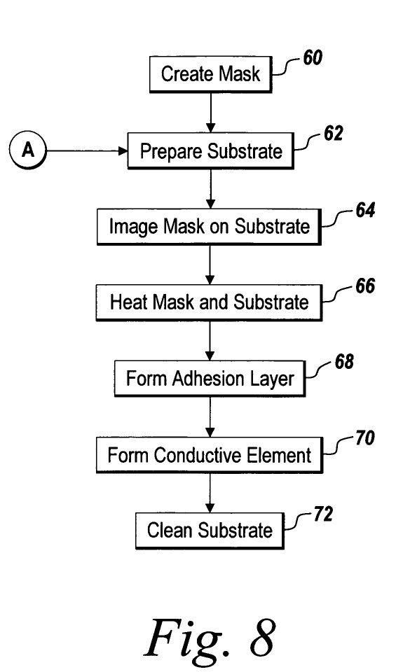

FIG. 7 illustrates the substrate 40 following completion of a cleaning or removal process to remove the mask 42 therefrom. Upon removal of the mask 42 a portion of the first surface 44 of substrate 40 previously covered by the mask 42 is free of the mask 42 and overlying layers, such as the adhesion layer 48 and the conductive element 50. Likewise, portions of the adhesion layer 48 and the conductive element 50 remain affixed to those portions of the first surface 44 of the substrate 40 where no mask 42 was formed on the first surface 44 of the substrate 40. The remaining adhesion layer 48 and conductive element 50 have a structure and pattern defined by the mask 42.

FIG. 8 illustrates the steps taken to form the structure illustrated in FIG. 7. In step 60, a user of computer system 10 creates the mask 42. In step 62, the user prepares the substrate 40 for imaging the mask 42 thereon. Preparation of the substrate 42 can include, but is not limited to, cleaning a surface of the substrate 40, affixing the substrate 40 to a stiffener, such as a sheet of paper or other suitable medium, or coating a surface of the substrate 40 with a dielectric. Suitable dielectrics include, but are not limited to silicon nitride (SiNₓ), silicon nitride (Si₃N₄), or silicon dioxide (SiO₂). The thickness of a precoat dielectric can be up to about 500 nm.

In step 64, image forming apparatus 14A or 14B forms on the substrate 40 the mask 42. The image forming apparatus 14A or 14B receives the image of the mask 42 from the application 28. The formation of the mask 42 in step 64 can occur on a clean substrate 40 free of a dielectric layer or on the substrate 40 with a dielectric layer.

In step 66, the substrate 40 and the mask 42 are heated to an elevated temperature, for example in an oven. The elevated temperature is between about 100° C. and about 150° C. The period of heating the substrate 40 and the mask 42 can range between about 1 second and about 2000 seconds.

In step 68, the adhesion layer 48 is formed. Formation of the adhesion layer 48 takes place in the vacuum chamber 30 using the material source 34. Material source 34 deposits on a surface of the substrate 40 and the mask 42 a selected material or compound to form the adhesion layer 48. Such suitable material sources include, but are not limited to sputterers, spraying apparatuses, electron beam evaporators, thermal evaporators, electrode platters, and electrodeless platters. The material or compound selected to form the adhesion layer 48 can be a conductive or semiconductive material. Suitable materials for use as the adhesion layer 48 include, but are not limited chromium (Cr), nickel (Ni), titanium (Ti), aluminum (Al), copper (Cu), silicon dioxide (SiO₂), and silicon nitride (SiNₓ). Suitable thicknesses of the adhesion layer 48 can range between about 50 Angstroms to about 100 Angstroms or about 5 nanometers to about 10 nanometers. Those skilled in the art will appreciate that the material composition of the adhesion layer 48 can have the same chemical composition as a dielectric layer used to precoat a surface of substrate 40.

In step 70, the conductive element 50 is formed in the vacuum chamber 30 using the material source 34 as the workpiece holder 32 holds the substrate 40. Material source 34 deposits on a surface of the adhesion layer 48 a selected material or compound to form the conductive element 50. Such suitable material sources include, but are not limited to sputterers, spraying apparatuses, electron beam evaporators, thermal evaporators, chemical vapor deposition tools, enhanced chemical vapor deposition tools, electrode platters, and electrodeless platters. The material or compound selected to form the conductive element 50 can be a conductive or semiconductive material. Suitable materials for use as the conductive element 50 include, but are not limited chromium (Cr), nickel (Ni), copper (Cu), aluminum (Al), titanium (Ti), gold (Au), copper (Cu), silicon dioxide (SiO₂), or other material or compound. Suitable thicknesses of the conductive element 50 can range between about 50 Angstroms to about 1000 Angstroms or about 5 nanometers to about 100 nanometers.

In step 72, the substrate 40 is cleaned using a suitable cleaning technique to remove mask 42 from the substrate 40. Those skilled in the art will recognize there exist a number of suitable cleaning techniques to remove the mask 42 at any time after the formation of the conductive element 50. Moreover, those skilled in the art will recognize that the suitable cleaning techniques may be combined in a number of manners to facilitate the cleaning process. Examples of cleaning techniques include, but are not limited to, ultrasonic cleaning, rubbing with a swab, pulse jet sprays. Any or all of these techniques can be used alone or in combination with solvents such as 1,1,1-trichloroethane (TCE), solvents from the ketone group, such as acetone, methylisobutyl ketone; the aromatic solvent group such as toluene, xylene; the ester group, such as ethyl acetate, methoxypropyl acetate; ether group such as diethyl ether, and other commonly used solvents such as dimethyl formamide, N-methylpyrolidone, or gamma-butyrolactone.

FIG. 9 illustrates steps taken to form a double sided electronic circuit in accordance with the teachings of the present invention. In step 60, mask 42 is created using computer system 10. In step 74, it is decided if the electronic circuit is double sided. Those skilled in the art will recognize that the decision to form a double sided electronic circuit can take place before or during step 60, creation of the mask. If the electronic circuit is a single sided electronic circuit or it is decided to process a double sided electronic circuit one side at a time the process proceeds to step 62 in FIG. 8. If in step 74, it is decided to produce a double sided electronic circuit, the process flows to step 76 in which the substrate is prepared. Those skilled in the art will appreciate that steps 76-92 parallel and are analogous to steps 62-72 detailed in connection with FIG. 8. Moreover, those skilled in the art will recognize that in the formation of a double sided electronic circuit a first side of the substrate 40 can be formed according to the teachings of the present invention before the second surface of the substrate 40 is process to fabrication the second side of the double sided electronic circuit. Furthermore, those skilled in the art will appreciate that the structural elements of the electronic circuit formed on the first surface of the substrate 40 and the structural elements of the electronic circuit formed on the second surface of the substrate 40 can be formed in alternating fashion so that in one step the mask is formed on the first surface and in a next step the mask is formed on a second surface and so on until the desired double sided electronic circuit is formed on the substrate 40. Further, those skilled in the art will appreciate that the actual sequencing of steps taken are flexible enough to suit any desired processing requirements based on material availability, manpower, and station time in a vacuum chamber to form the various structural components.

In step 78, the computer system 10 images the mask 42 on the first surface 44 of substrate 40 using the image forming apparatus 14A or 14B. In step 80, the computer system 10 forms mask 42 on the second surface 46 of substrate 40 using the image forming apparatus 14A or 14B. Those skilled in the art will appreciate that the mask formed on the first surface 44 of the substrate 40 can define one or more structural features distinct from the mask formed on the second surface 46 of the substrate 40 and vice versa.

In step 82, the substrate 40 and the mask 42 are heated to an elevated temperature for a selected period of time. In step 84, the adhesion layer 48 is formed on the first surface 44 of the substrate 40. In step 86, the conductive element 50 is formed on the adhesion layer 48 of the first surface 44 of the substrate 40. In step 88, the adhesion layer 48 is formed on the second surface 46 of the substrate 40. In step 90, the conductive element 50 is formed on the adhesion layer 48 of the second surface of the substrate 40. In step 92, the processed substrate 40 is cleaned to remove the mask from the first surface 44, the second surface 46, or both.

The adhesion layer 48 enables the fabrication of structures that are otherwise unfeasible to fabricate due to delamination of a conductive layer from a substrate. For example, gold and aluminum have poor adhesion properties and delaminate readily from polymeric surfaces. In accordance with the teachings of the present invention, gold can be deposited on polyester without delamination using an adhesion layer of titanium. The present invention provides an adhesion layer that offers a connective structure between the substrate and the conductive layer. This adhesion layer can also be beneficial in improving electrical properties. For example, chromium deposited directly on a polyimide such as “Kapton® E” using Electron-beam deposition has poor electrical conductivity, whereas Electron-beam deposition of chromium over an adhesive layer of titanium results in improved conductivity. The adhesion layer can also prevent the propagation of cracks in the substrate, an insulating layer in contact with the substrate, and a conductive layer in contact with the insulating layer, or the substrate, or both, during bending, to result in an improvement in the length of a life cycle for flexible circuits.

To illustrate the flexibility and the processing of a substrate according to the teachings of the present invention, seven examples are discussed below in detail.

### EXAMPLE I

A conductive pattern is fabricated on substrate 40 according the teachings of the present invention. Substrate 40 is polyimide (Kapton® E) film having thickness of about 51 μm. The polyimide film is removably attached to an 8½×11 sheet of paper (stiffener) by means of mounting tape. A negative electrophotographic imaging compound pattern is imaged on the polyimide film attached to the sheet of paper as stiffener using a laser printer, for example a Hewlett Packard LaserJet 5P, available from Hewlett Packard of Palo Alto, Calif. The sheet of paper is removed and the electrophotographic imaging compound and the polyimide film are baked in air for about one minute at a temperature of about 120° C. About a 10 nm thick layer of chromium (Cr) is deposited by Electron-beam evaporation on the polyimide film and the electrophotographic imaging compound under vacuum to form an adhesion layer. A layer of titanium (Ti) follows the layer of Cr. The Ti has a thickness of about 100 nm is deposited by Electron-beam evaporation. The polyimide film with the layers of Cr and Ti is placed in an ultrasonic toluene bath and agitated for 1 minute. The ultrasonic bath is repeated once and the polyimide film is washed with 1,1,1 trichloroethane to quantitatively remove electrophotographic imaging compound and overlying metal layers.

### EXAMPLE II

Using a substrate 40 of polyimide (Kapton® E) film having a thickness of about 51 μm a conductive pattern is fabricated thereon. The polyimide film is temporarily attached to a sheet of 8½×11 paper (stiffener) by means of mounting tape. A negative electrophotographic imaging compound pattern is imaged on the polyimide film using a laser printer for example a Hewlett Packard LaserJet 5P, available from Hewlett Packard of Palo Alto, Calif. The sheet of paper is removed from the polyimide film and the electrophotographic imaging compound and the polyimide film are baked in air for about 1 minute at about 120° C. About a 10 nm thick layer of Ti is deposited by Electron-beam evaporation on the polyimide film and the electrophotographic imaging compound under vacuum to form an adhesion layer. Next, about a 100 nm thick layer of gold (Au) is deposited by Electron-beam evaporation on the layer of Ti under vacuum. The polyimide film with the layers of Ti and Au is rubbed with a foam swab in a 1,1,1 trichloroethane/acetone bath to remove the electrophotographic imaging compound and overlying metal layers. The cleaning process is repeated once and the polyimide film is washed with acetone and dried to yield a photographic quality image on polyimide film.

### EXAMPLE III

Using an overhead transparency or a piece of polyester film having a thickness of about 5 mil for substrate 40, a conductive pattern is fabricated as shown in FIG. 7. A negative electrophotographic imaging compound pattern is imaged on the transparency/polyester film using a laser printer, for example a Hewlett Packard LaserJet 5P, available from Hewlett Packard of Palo Alto, Calif. No stiffener is used. The electrophotographic imaging compound and transparency/polyester film is baked in air for about one minute at a temperature of about 120° C. Next, a layer of Ti having a thickness of about 10 nm is deposited on electrophotographic imaging compound and transparency/polyester film the by Electron-beam evaporation under vacuum to form an adhesion layer. The layer of Ti is followed by another Electron-beam evaporation process under vacuum to form a layer of Au having a thickness of about 100 nm on the layer of Ti. The transparency/polyester film with the layer of Ti and Au is lightly rubbed with swabs in a 1,1,1-trichloroethane bath. This cleaning process is repeated once with new solvent and the sample is washed with 1,1,1-trichloroethane to quantitatively remove the layer of electrophotographic imaging compound and overlying metal layers.

### EXAMPLE IV

Using a substrate 40 of polyimide (Kapton® E) film having a thickness of about 51 μm a conductive pattern is fabricated thereon. The polyimide film is temporarily attached to a sheet of 8½×11 paper (stiffener) by means of mounting tape. A negative electrophotographic imaging compound pattern is imaged on the polyimide film using a laser printer, for example a Lexmark Optra S 1255, available from Lexmark International, Inc. of Lexington, Ky. Next, a first layer silicon dioxide (SiO₂) is deposited on the polyimide film and the electrophotographic imaging compound under vacuum using a sputterer to form an adhesion layer. A second layer of SiO₂ is deposited over the first layer of SiO₂ under vacuum using a sputterer. Each layer of SiO₂ has a thickness of about 50 nm. One suitable sputterer for use with the teachings of the present invention is available from AJA International, Inc. of Scituate, Mass. To clean the workpiece, the polyimide film with the two layers of SiO₂ is placed in an ultrasonic toluene bath and agitated for about one minute. The workpiece is then lightly rubbed with swabs in a 1,1,1-trichloroethane bath. This light rubbing process is repeated once with new solvent and the workpiece is washed with 1,1,1-trichloroethane in order to quantitatively remove electrophotographic imaging compound and overlying SiO₂ layers.

### EXAMPLE V

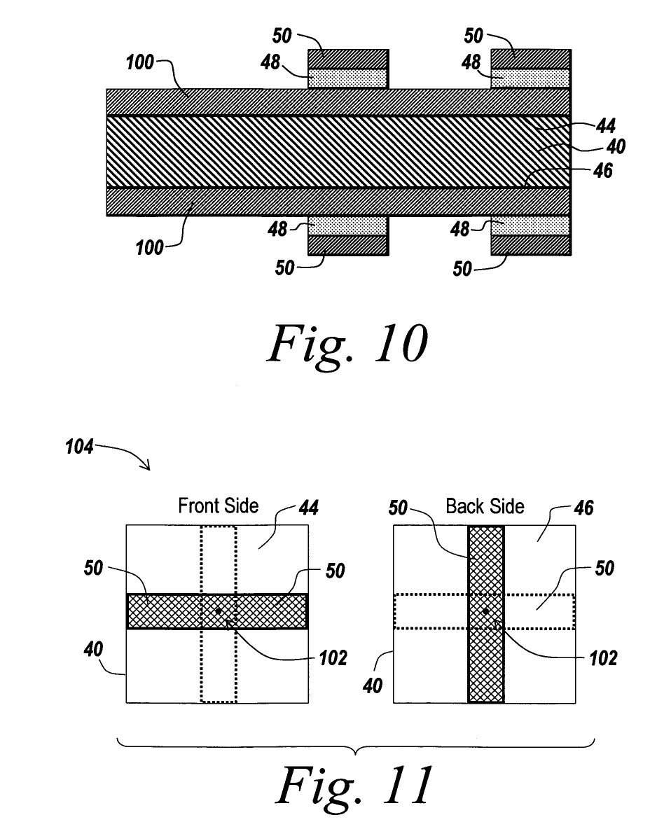

Using a substrate 40 of polyimide (Kapton® E) film having a thickness of about 51 μm a metalized pattern is fabricated thereon. Before imaging the polyimide film with electrophotographic imaging compound, the polyimide film is coated with SiNₓ on a top surface and a bottom surface, as illustrated in FIG. 10. Each coating or layer of SiNₓ has a thickness of about 500 nm. The SiNₓ is deposited on the top surface and the bottom surface of the polyimide using a plasma enhanced chemical vapor deposition (PECVD) tool, for example, using a PECVD tool available from Innovative Systems Engineering of Warminster, Pa. Once coated, the polyimide film is temporarily attached to a sheet of 8½×11 paper (stiffener) by means of mounting tape. A negative electrophotographic imaging compound pattern is imaged on the coated polyimide film using a laser printer, for example a Lexmark Optra S 1255, available from Lexmark International, Inc. of Lexington, Ky. Next, a layer of Cr is deposited on a portion of a first coated surface and the electrophotographic imaging compound pattern to form an adhesion layer. The thickness of the Cr layer is about 10 nm. Formation of the Cr or adhesion layer is followed by deposition of a layer of Ti by Electron-beam evaporation under vacuum. The Ti layer has a thickness of about 100 nm layer. The polyimide film with the coating, the layer of electrophotographic imaging compound, the layer of Cr, and the layer of Ti is placed in an ultrasonic toluene bath and agitated for about one minute. The polyimide film with the various layers is lightly rubbed with swabs in a 1,1,1 trichloroethane bath. This light rubbing process is repeated once with new solvent and the polyimide film is washed with 1,1,1 trichloroethane to quantitatively remove the electrophotographic imaging compound and overlying metal layers.

### EXAMPLE VI

Using a substrate 40 of polyimide (Kapton® E) film having a thickness of about 51 μm a conductive pattern is fabricated thereon. The polyimide film is temporarily attached to a sheet of 8½×11 paper (stiffener) by means of mounting tape. A negative electrophotographic imaging compound pattern is imaged on the polyimide film using a laser printer for example a Hewlett Packard LaserJet 5P, available from Hewlett Packard of Palo Alto, Calif. The sheet of paper is removed from the polyimide film and the electrophotographic imaging compound and the polyimide film are baked in air for about 1 minute at about 120° C. Next, a layer of Cr is deposited by thermal evaporation on a portion of the polyimide film and the electrophotographic imaging compound pattern under vacuum to form an adhesion layer. The layer of Cr has a thickness of about 110 nm. The polyimide film is then rubbed with a foam swab in a 1,1,1 trichloroethane/acetone bath to remove the electrophotographic imaging compound and overlying metal layers. This process is repeated once and the polyimide film is washed with acetone and dried to yield a photographic quality image on polyimide.

### EXAMPLE VII

Using a substrate 40 formed from a 3″×3″ piece polyimide (Kapton® E) film having a thickness of about 51 μm thick a conductive pattern is fabricated thereon. In a center portion of the polyimide film a hole was punched with a punching means, such as a needle, awl, drill or other like punching means to create a via. See FIG. 11. The polyimide film is temporarily attached to a sheet of 8½×11 paper (stiffener) by means of mounting tape. A negative electrophotographic imaging compound pattern consisting of a 0.3 inch horizontal strip as illustrated in FIG. 11 was imaged on the front side of the polyimide film using a laser printer, for example a Lexmark Optra S 1255, available from Lexmark International, Inc. of Lexington, Ky.

Next, a layer of Cr is deposited by Electron-beam evaporation under vacuum on the electrophotographic imaging compound pattern and the front side of the polyimide film to form an adhesion layer. The layer of Cr has a thickness of about 10 nm thick. The layer of Cr is followed by a layer of Ti deposited by Electron-beam evaporation under vacuum. The layer of Ti has a thickness of about 100 μm. The polyimide film with the deposited layers is placed in an ultrasonic toluene bath and agitated for about one minute to remove the electrophotographic imaging compound. The polyimide film is then lightly rubbed with swabs in a 1,1,1 trichloroethane bath. This light rubbing process is repeated once with new solvent and the polyimide film is washed with 1,1,1 trichloroethane to quantitatively remove electrophotographic imaging compound and overlying metal layers from the front surface of the polyimide film.

The polyimide film is turned over and again temporarily attached again to a sheet of paper (stiffener). An electrophotographic imaging compound pattern is imaged on the bottom side of the polyimide using the laser printer. Next, a layer of Cr is deposited by Electron-beam evaporation under vacuum on the electrophotographic imaging compound pattern and the bottom side of the polyimide film to form an adhesion layer on the bottom side. The layer of Cr has a thickness of about 10 nm thick. The layer of Cr is followed by a layer of Ti deposited by Electron-beam evaporation under vacuum. The layer of Ti has a thickness of about 100 nm. The polyimide film is placed in an ultrasonic toluene bath and agitated for about one minute. The polyimide film is lightly rubbed with swabs in 1,1,1 trichloroethane bath. This light rubbing process is repeated once with new solvent and the polyimide film is washed with 1,1,1 trichloroethane to quantitatively remove the electrophotographic imaging compound on the overlying metal layers. Less than 100 Ω resistance was measured between the upper metallization pattern and the lower metallization pattern.

FIG. 10 illustrates the substrate 40 having the first surface 44 and the second surface 46 precoated with an inorganic compound 100. The inorganic compound 100 is applied to one or more surfaces of the substrate 40 prior to the formation of the mask 42 on the substrate 40. Inorganic compound 100, can be a dielectric such as SiNₓ, Si₃N₄, and SiO2 applied on selected surfaces of the substrate 40 and have a thickness of up to about 500 nm. The precoating of a surface of the substrate 40 with the inorganic compound 100 provides a substrate surface that is a barrier to moisture and solvent uptake by the underlying polymer film and can provide adhesion to the subsequent layers. As illustrated in FIG. 10, the adhesion layer 48 is in contact with the inorganic compound 100 and the conductive element 50 contacts a second surface of the adhesion layer 48.

FIG. 11 illustrates a top and bottom view of a double sided electronic circuit 104 formed in accordance with the teachings of the present invention. The electronic circuit 104 includes substrate 40 having formed on the first surface 44 conductive element 50 in contact with adhesion layer 48 (not shown) which, in turn, contacts the first surface 44. Likewise, on the bottom side of the substrate 40 or the second surface 46, the double sided electronic circuit 104 includes the conductive element 50 in contact with the adhesion layer 48 (not shown) which, in turn, is in contact with the second surface 46. Those skilled in the art will appreciate that as illustrated in FIG. 10, the adhesion layer 48 formed on the first surface 44, the second surface 46, or both can be in contact with the inorganic layer 100 formed on the first or second, or both surfaces of the substrate 40. The double sided electronic circuit 104 can include a via 102 to couple the conductive element 50 of the first surface 44 to the conductive element 50 of the second surface 46.

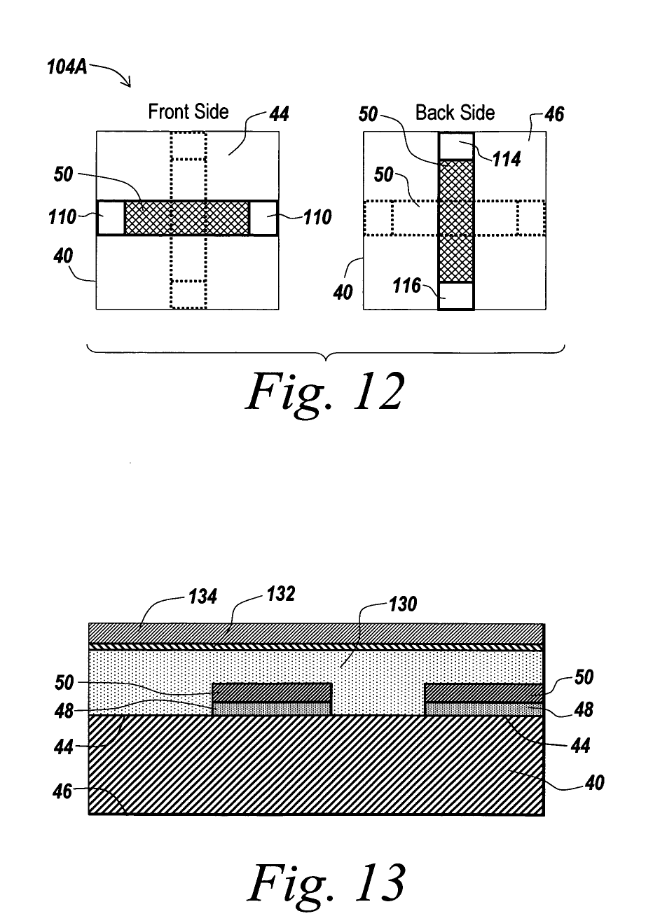

FIG. 12 illustrates a top and bottom view of a double sided electronic circuit 104A formed in accordance with the teachings of the present invention. The electronic circuit 104A includes substrate 40 having formed on the first surface 44 conductive element 50 in contact with adhesion layer 48 (not shown) which, in turn, contacts the first surface 44. The conductive element 50 couples the first electronic device 110 to the second electronic device 112. In this manner, the conductive element 50 is a transmission path for a power signal, an analog signal, or a digital signal. Likewise, on the bottom side of the substrate 40 or the second surface 46, the double sided electronic circuit 104A includes the conductive element 50 in contact with the adhesion layer 48 (not shown) which, in turn, is in contact with the second surface 46. The conductive element 50 on the second surface 46 couples the third electronic device 114 to the fourth electronic device 116. In this manner, the conductive element 50 is a transmission path for a power signal, an analog signal, or a digital signal. Those skilled in the art will appreciate that as illustrated in FIG. 10, the adhesion layer 48 formed on the first surface 44, the second surface 46, or both can be in contact with the inorganic layer 100 formed on the first or second, or both surfaces of the substrate 40. Moreover, those skilled in the art will appreciate that the conductive element 50 can interconnect an electronic device on a single sided substrate of electronic circuit.

FIG. 13 illustrates a side view of an electronic display having an electronic circuit fabricated in accordance with the teachings of the present invention. Electronic display 140 includes the substrate 40 having formed on at least one surface the adhesion layer 48 and the conductive element 50. The electronic display 140 also includes display media 130, indium tin oxide (ITO) conductive layer 132, and polyester backing film 134. Suitable display media 130 includes bi-stable electronic inks and liquid crystalline media such as polymer-dispersed liquid crystals. The term “electronic ink” as used herein is intended to include any suitable bi-stable, non-volatile display material. The term “bi-stable” as used herein is intended to indicate that the particles of the imaging material can alternately occupy two stable states.

According to one practice, a microcup® is filled with electrically charged white particles in a black or colored dye. Electrodes can be disposed on, cover, or both opposite sides of the media for use in applying a voltage potential difference across the electronic ink to cause particles within the microcapsules to migrate toward one of the electrodes. This migration can change the color of the microcup, and hence the pixel location, as viewed by an individual. One example of an electronic display 140 and other examples of display media 130 are discussed in detail in U.S. Pat. No. 6,753,830, entitled “Smart Electronic Label Employing Electronic Ink”, the contents of which are incorporated hereby incorporated by reference. Another example of an electronic display 140 and other examples of display media 130 are discussed in detail in U.S. Provisional Application Ser. No. 60/550,091, filed Mar. 1, 2004, the contents of which are hereby incorporated by reference.

Those skilled in the art will recognize the term microcup® refers to one or more electrophoretic display cells having a structure as disclosed in U.S. Pat. No. 6,753,067, entitled “Microcup Compositions Having Improved Flexure Resistance And Release Properties”, the contents of which are hereby incorporated by reference.

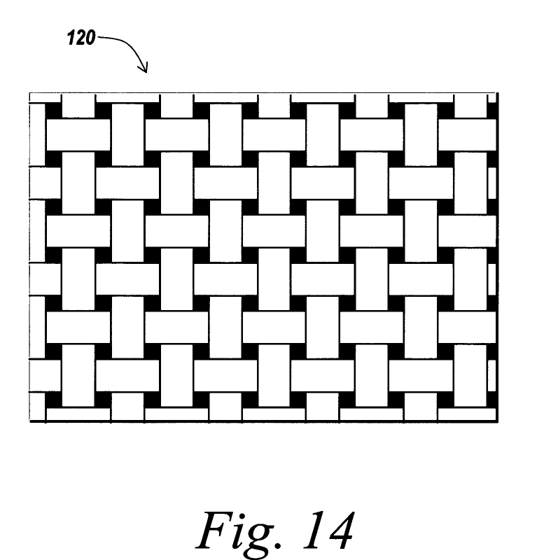

FIG. 14 illustrates a fabric material 120 suitable for use as a substrate 40 in accordance with the teachings of the present invention. Fabric material 120 can be a woven fabric as illustrated and as such graphical and textual designs formed with application 28 can be transferred to the fabric material 120 using the image forming apparatus 14A or 14B and metalized to provide a decorative image on clothes or other goods, such as furniture, drapery, linens, towels, headwear, footwear and other like products that use fabric.

It will thus be seen that the invention efficiently attains the objects set forth above, amongst those made apparent from the preceding discussion. Since certain changes may be made in the above constructions, for example, additional layers of compounds and materials can be formed in addition to the layers discussed herein, that is, backplanes or electronic devices having a three layer, four layer, a five layer, a six layer, a seven layer, an eight layer, a nine layer, ten layer, eleven layer, construction are well within the scope of the present invention. It is intended that all matter contained in the above description are shown in the accompanying drawings be interpreted as illustrative and not in a limiting sense.

It is also to be understood that the following claims are to cover all generic and specific features of the invention described herein, and all statements are of the scope of the invention which, as a matter of language, might be said to fall therebetween.

1) A method for coupling a conductive element to a substrate, the method comprising the steps of
forming an adhesion layer on a portion of the first surface of the substrate; and
forming the conductive element on the adhesion layer to couple the conductive element to the substrate.

2) The method of claim 1, further comprising the step of forming a mask of an electrophotographic imaging compound on the first surface of the substrate.

3) The method of claim 2, further comprising the step of heating the substrate with the mask formed thereon to an elevated temperature for a selected period of time.

4) The method of claim 2, further comprising the step of removing at least a portion of the mask from the first surface of the substrate.

5) The method of claim 1, further comprising the step of affixing the substrate to a stiffener.

6) The method of claim 1, further comprising the steps of
forming an adhesion layer on a portion of a second surface of the substrate; and
forming the conductive element on the adhesion layer formed on the second surface of the substrate.

7) The method of claim 6, further comprising the step of forming a mask of an electrophotographic imaging compound on the second surface of the substrate.

8) The method of claim 7, further comprising the step of heating the substrate with the mask formed thereon to an elevated temperature for a selected period of time.

9) The method of claim 7, further comprising the step of removing at least a portion of the mask from the second surface of the substrate.

10) The method of claim 1, further comprising the step of forming a dielectric layer on a portion of the first surface of the substrate.

11) The method of claim 10, wherein the dielectric layer comprises silicon nitride (SiNₓ).

12) The method of claim 10, wherein the dielectric layer comprises silicon nitride (Si₃N₄).

13) The method of claim 10, wherein the dielectric layer comprises silicon dioxide (SiO₂).

14) The method of claim 10, wherein the dielectric layer and the adhesion layer comprises a like material composition.

15) The method of claim 1, further comprising the step of plasma etching at least the first surface of the substrate.

16) The method of claim 1, wherein the substrate comprises glass.

17) The method of claim 1, wherein the substrate comprises glass foil.

18) The method of claim 1, wherein the substrate comprises silicon.

19) The method of claim 1, wherein the substrate comprises a rigid substrate.

20) The method of claim 1, wherein the substrate comprises a polymeric substrate.

21) The method of claim 20, wherein the polymeric substrate comprises a flexible polymeric substrate.

22) The method of claim 21, wherein the flexible polymeric substrate comprises a polyimide.

23) The method of claim 21, wherein the flexible polymeric substrate comprises a polybenzimidazole.

24) The method of claim 21, wherein the flexible polymeric substrate comprises a polyvinyl.

25) The method of claim 21, wherein the flexible polymeric substrate comprises a polyester.

26) The method of claim 21, wherein the flexible polymeric substrate comprises a polyacrylate.

27) The method of claim 21, wherein the flexible polymeric substrate comprises a polyamide.

28) The method of claim 21, wherein the flexible polymeric substrate comprises a celluloid.

29) The method of claim 1, wherein the substrate comprises a fabric.

30) The method of claim 29, wherein the fabric comprises a woven fabric.

31) The method of claim 1, wherein the substrate comprises a lignocellulosic material.

32) The method of claim 1, wherein the adhesion layer comprises an insulating material.

33) The method of claim 32, wherein the insulating material comprises silicon dioxide (SiO₂).

34) The method of claim 32, wherein the insulating material comprises silicon nitride (SiNₓ).

35) The method of claim 1, wherein the adhesion layer comprises at least one metalized layer.

36) The method of claim 35, wherein the at least one metalized layer comprises titanium (Ti).

37) The method of claim 35, wherein the at least one metalized layer comprises chromium (Cr).

38) The method of claim 35, wherein the at least one metalized layer comprises copper (Cu).

39) The method of claim 35, wherein the at least one metalized layer comprises aluminum (Al).

40) The method of claim 35, wherein the at least one metalized layer comprises nickel (Ni).

41) The method of claim 1, wherein the step of forming the adhesion layer comprises the step of depositing the adhesion layer with an electron beam evaporator.

42) The method of claim 1, wherein the step of forming the adhesion layer comprises the step of depositing the adhesion layer using chemical vapor deposition.

43) The method of claim 1, wherein the step of forming the adhesion layer comprises the step of depositing the adhesion layer using plasma enhanced chemical vapor deposition.

44) The method of claim 1, wherein the step of forming the adhesion layer comprises the steps of
thermally evaporating a selected material; and
depositing the selected material on the portion of the first surface of the polymeric substrate.

45) The method of claim 1, wherein the step of forming the adhesion layer comprises the step of plating the portion of the first surface of the substrate to form the adhesion layer.

46) The method of claim 45, wherein the step of plating is performed with one or more electrodes.

47) The method of claim 45, wherein the step of plating is performed in an electrodeless manner.

48) The method of claim 1, wherein the step of forming the adhesion layer comprises the step of sputtering the portion of the first surface of the substrate to form the adhesion layer.

49) The method of claim 1, wherein the step of forming the adhesion layer comprises the step of spraying a selected material on the portion of the first surface of the substrate to form the adhesion layer.

50) An electronic circuit comprising,
a substrate, and
an adhesion layer in contact with a portion of a first surface of the substrate, and
a conductive path in contact with a portion of the adhesion layer, the conductive path coupling a portion of a first electronic device of the electronic circuit to a portion of a second electronic device of the electronic circuit.

51) The electronic circuit of claim 50, further comprising a dielectric layer in contact with a portion of the substrate and a portion of the adhesion layer.

52) The electronic circuit of claim 50, further comprising
an adhesion layer in contact with a portion of a second surface of the substrate, and
a conductive path in contact with a portion of the adhesion layer in contact with the portion of the second surface of the substrate, the conductive path coupling a portion of a third electronic device of the electronic circuit to a portion of a fourth electronic device of the electronic circuit.

53) The electronic circuit of claim 50, wherein the adhesion layer comprises a material having electrically conductive properties.

54) The electronic circuit of claim 50, wherein the conductive path comprises a metalized layer.

55) The electronic circuit of claim 50, wherein the substrate comprises a polymeric substrate.

56) The electronic circuit of claim 55, wherein the polymeric substrate comprises a flexible polymeric substrate.

57) The electronic circuit of claim 50, wherein the first electronic device comprises at least one of a transistor, a resistor, a capacitor, and an inductor.

58) An electronic circuit comprising,
a substrate, and
a via coupling a first conductive path in contact with a first adhesion layer formed on a first surface of the substrate to a second conductive path in contact with a second adhesion layer formed on a second surface of the substrate to couple the first conductive path to the second conductive path.

59) The electronic circuit of claim 58, wherein at least one of the first adhesion layer and the second adhesion layer comprises a material having electrically conductive properties.

60) The electronic circuit of claim 58, wherein at least one of the first conductive path and the second conductive path comprises a metalized layer.

61) The electronic circuit of claim 58, wherein the substrate comprises a polymeric substrate.

62) The electronic circuit of claim 60, wherein the polymeric substrate comprises a flexible polymeric substrate.

63) The electronic circuit of claim 60, wherein the first conductive path couples a portion of a first electronic device to a second electronic device.

64) The electronic circuit of claim 63, wherein the first electronic device comprises at least one of a transistor, a resistor, a capacitor, and an inductor.

65) The electronic circuit of claim 60, wherein the second conductive path couples a portion of a third electronic device to a fourth electronic device.

66) The electronic circuit of claim 65, wherein the third electronic device comprises at least one of a transistor, a resistor, a capacitor, and an inductor.

67) An electronic display, comprising
an electrophotgraphically imaged backplane,
an electrophoretic display medium coupled to the electrophotgraphically imaged backplane, and
a common electrode coupled to the electrophoretic display medium.

68) The electronic display of claim 67, wherein the electrophotgraphically imaged backplane comprises,
a substrate,
an adhesion layer coupled to a surface of the substrate, and
a conductive element coupled to the adhesion layer.

69) The electronic display of claim 67, wherein the electrophoretic display medium comprises, at least one of a bi-stable, non-volatile imaging material, a gyricon material, cholesteric material, a zenithal bi-stable device material, a thermo-chromic material, surface stabilized, ferroelectric liquid crystals, and an electrophoretic material having a plurality of portioned cells, each cell having a plurality of walls and an electrophoretic fluid filled therein.
